(19) United States
(12) Patent Application Publication
(10) Pub. No.: US 2025/0324613 A1
(43) Pub. Date: Oct. 16, 2025

(54) SEMICONDUCTOR DEVICE AND METHOD FOR FABRICATING THE SAME

(71) Applicant: SK hynix Inc., Icheon-si (KR)

(72) Inventors: Jeong Hoon Bae, Icheon-si (KR); Jeong Ho Yeon, Icheon-si (KR); Nam Kyun Park, Icheon-si (KR)

(21) Appl. No.: 19/081,889

(22) Filed: Mar. 17, 2025

(30) Foreign Application Priority Data
Apr. 11, 2024 (KR) 10-2024-0048728

(51) Int. Cl. H10B 63/00

(52) U.S. Cl. CPC H10B 63/80

(57) ABSTRACT

A semiconductor device includes: a substrate including a cell area, a first peripheral circuit area disposed adjacent to the cell area in a first direction, and a second peripheral circuit area disposed adjacent to the cell area in a second direction intersecting with the first direction; first lower conductive lines disposed over the substrate, extending in the first direction; first memory cells disposed in intersection regions between the first lower conductive lines and the first segments of the first upper conductive patterns; second lower conductive lines extending in the second direction and disposed over the first upper conductive patterns; second upper conductive lines disposed over the second lower conductive lines, extending in the first direction, and crossing both the cell area and the first peripheral circuit area; and second memory cells disposed in intersection regions between the second lower conductive lines and the second upper conductive lines.

### CROSS-REFERENCE TO RELATED APPLICATION

The present application claims priority under 35 U.S.C 119 (a) to Korean Patent Application No. 10-2024-0048728, filed on Apr. 11, 2024, in the Korean Intellectual Property Office, which is incorporated herein by reference in its entirety.

### BACKGROUND

### 1. Field

Embodiments of the present disclosure relate to a semiconductor technology, and more particularly, to a semiconductor device having a cross-point structure in which memory cells are arranged between lower conductive lines and upper conductive lines that intersect with each other, and a method for fabricating the semiconductor device.

### 2. Description of the Related Art

Recent trends for miniaturization, low-power consumption, high performance, and diversification of electronic devices require semiconductor devices that may store data in diverse electronic devices, such as computers and portable communication devices, and researchers and the industry are studying to develop the semiconductor devices. Such semiconductor devices include semiconductor devices that may store data by using the characteristics of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device that prevents defects in near memory cells and ensure the normal operation of all memory cells, and a method for fabricating the semiconductor device.

In accordance with an embodiment of the present invention, a semiconductor device includes: a substrate including a cell area, a first peripheral circuit area disposed adjacent to the cell area in a first direction, and a second peripheral circuit area disposed adjacent to the cell area in a second direction intersecting with the first direction, the first and second directions being parallel to a top surface of the substrate; a plurality of first lower conductive lines disposed over the substrate, extending in the first direction, and crossing both the cell area and the first peripheral circuit area; a plurality of first upper conductive patterns disposed over the first lower conductive lines, extending in the second direction, and crossing both the cell area and the second peripheral circuit area, each of the first upper conductive patterns including a first segment disposed in the cell area and a second segment disposed in the second peripheral circuit area, the second segment being separated from the first segment; a plurality of first memory cells disposed in intersection regions between the first lower conductive lines and the first segments of the first upper conductive patterns; a plurality of second lower conductive lines extending in the second direction and disposed over the first upper conductive patterns, each of the second lower conductive lines overlapping with and contacting a corresponding one of the first upper conductive patterns; a plurality of second upper conductive lines disposed over the second lower conductive lines, extending in the first direction, and crossing both the cell area and the first peripheral circuit area; and a plurality of second memory cells disposed in intersection regions between the second lower conductive lines and the second upper conductive lines.

In accordance with another embodiment of the present invention, a method for fabricating a semiconductor device includes: providing a substrate including a cell area, a first peripheral circuit area disposed adjacent to the cell area in a first direction, and a second peripheral circuit area disposed adjacent to the cell area in a second direction intersecting with the first direction, the first and second directions being parallel to a top surface of the substrate; forming a plurality of first lower conductive lines that are disposed over the substrate, extend in the first direction, and cross both the cell area and the first peripheral circuit area; forming a plurality of first upper conductive patterns that are disposed over the first lower conductive lines, extend in the second direction, and cross both the cell area and the second peripheral circuit area, each of the first upper conductive patterns including a first segment disposed in the cell area and a second segment disposed in the second peripheral circuit area, the second segment being separated from the first segment; forming a plurality of first memory cells that are disposed in intersection regions between the first lower conductive lines and the first segments of the first upper conductive patterns; forming a plurality of second lower conductive lines that extend in the second direction and are disposed over the first upper conductive patterns, each of the second lower conductive lines overlapping with and contacting a corresponding one of the first upper conductive patterns; forming a plurality of second upper conductive lines that are disposed over the second lower conductive lines, extend in the first direction, and cross both the cell area and the first peripheral circuit area; and forming a plurality of second memory cells that are disposed in intersection regions between the second lower conductive lines and the second upper conductive lines.

### BRIEF DESCRIPTION OF THE DRAWINGS

FIG. 1 is a perspective view illustrating a semiconductor device in accordance with an embodiment of the present disclosure.

FIGS. 2A to 8C illustrate a method for fabricating a semiconductor device in accordance with another embodiment of the present disclosure.

FIG. 9 is a plan view illustrating a semiconductor device in accordance with another embodiment of the present disclosure.

### DETAILED DESCRIPTION

Hereinafter, embodiments of the present disclosure will be described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

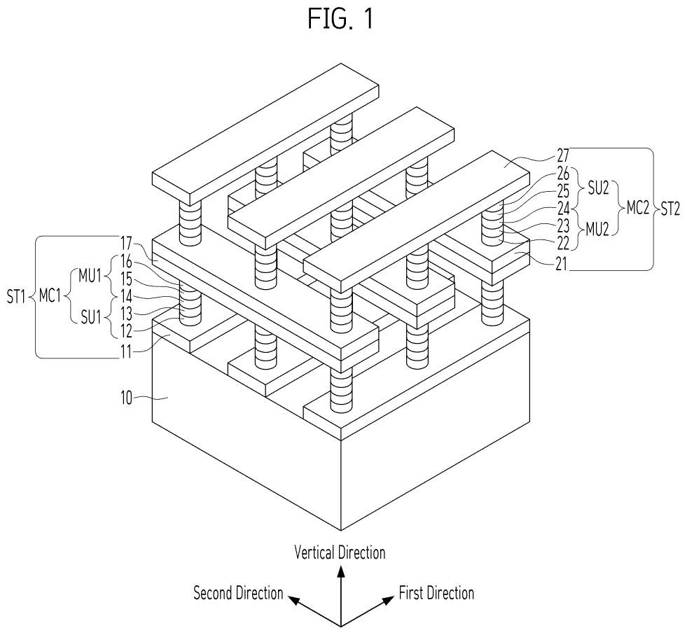

FIG. 1 is a perspective view illustrating a semiconductor device in accordance with an embodiment of the present disclosure.

Referring to FIG. 1, the semiconductor device may include a substrate 10, a first stacked structure ST1 formed over the substrate 10 and including a first lower conductive line 11, a first upper conductive line 17, and a first memory cell MC1, and a second stacked structure ST2 formed over the first stacked structure ST1 and including a second lower conductive line 21, a second upper conductive line 27, and a second memory cell MC2.

The substrate 10 may include a semiconductor material, such as silicon. Also, a required predetermined lower structure (not shown) may be formed in the substrate 10. For example, a driving circuit for driving at least one among the first lower conductive line 11, the first upper conductive line 17, the second lower conductive line 21, and the second upper conductive line 27 may be formed in the substrate 10.

The first lower conductive line 11 may extend in a first direction. A plurality of first lower conductive lines 11 may be arranged to be spaced apart from each other in a second direction crossing the first direction and may be disposed at the same level in a vertical direction. Herein, the first direction and the second direction may correspond to horizontal directions that are substantially parallel to a top surface of the substrate 10. The vertical direction may correspond to a direction that is substantially perpendicular to the top surface of the substrate 10. The first lower conductive line 11 may include one or more of various conductive materials. For example, the first lower conductive line 11 may include a metal such as platinum (Pt), tungsten (W), aluminum (Al), copper (Cu), tantalum (Ta), or the like; a metal nitride such as titanium nitride (TIN), tantalum nitride (TaN), or the like; or a combination thereof.

The first upper conductive line 17 may extend in the second direction. A plurality of first upper conductive lines 17 may be arranged to be spaced apart from each other in the first direction and may be disposed at the same level in the vertical direction. The first upper conductive line 17 may be disposed over the first lower conductive line 11 to be spaced apart from the first lower conductive line 11 in the vertical direction. The first upper conductive line 17 may include one or more of various conductive materials. For example, the first upper conductive line 17 may include a metal such as platinum (Pt), tungsten (W), aluminum (Al), copper (Cu), tantalum (Ta), or the like; a metal nitride such as titanium nitride (TiN), tantalum nitride (TaN), or the like; or a combination thereof.

A plurality of first memory cells MC1 may be disposed between the first lower conductive lines 11 and the first upper conductive lines 17, each overlapping with the intersection region between the first lower conductive lines 11 and the first upper conductive lines 17. The first memory cell MC1 may include a first memory unit MU1, where data are actually stored, and a first selector unit SU1, which controls access to the first memory unit MU1.

For example, the first memory cell MC1 may include a stacked structure of a first lower electrode layer 12, a first selector layer 13, a first middle electrode layer 14, a first variable resistance layer 15, and a first upper electrode layer 16. Herein, the first selector unit SU1 may include the first lower electrode layer 12, the first selector layer 13, and the first middle electrode layer 14. The first memory unit MU1 may include the first middle electrode layer 14, the first variable resistance layer 15, and the first upper electrode layer 16. The first middle electrode layer 14 may be shared by the first selector unit SU1 and the first memory unit MU1.

The first lower electrode layer 12 and the first upper electrode layer 16 may be disposed at both ends of the first memory cell MC1, that is, at the bottom and top ends, respectively, to transfer voltage or current that is required for an operation of the first memory cell MC1. The first middle electrode layer 14 may function to electrically connect the first selector layer 13 and the first variable resistance layer 15 while physically separating them from each other. The first lower electrode layer 12, the first middle electrode layer 14, and the first upper electrode layer 16 may each include one or more of various conductive materials. For example, the first lower electrode layer 12, the first middle electrode layer 14, and the first upper electrode layer 16 may each include a metal such as platinum (Pt), tungsten (W), aluminum (Al), copper (Cu), tantalum (Ta), titanium (Ti), or the like; a metal nitride such as titanium nitride (TiN), tantalum nitride (TaN), or the like; or a combination thereof. Also, the first lower electrode layer 12, the first middle electrode layer 14, and the first upper electrode layer 16 may each include a carbon electrode.

The first selector layer 13 may control the access to the first variable resistance layer 15 and prevent current leakage that may occur between the first memory cells MC1 sharing the first lower conductive line 11 or the first upper conductive line 17. To this end, the first selector layer 13 may exhibit threshold switching characteristics, blocking or minimally allowing current flow when the voltage supplied to the top and bottom ends of the first selector layer 13 is lower than a predetermined threshold voltage, and allowing current to flow rapidly when the voltage is equal to or higher than the threshold voltage. In other words, the first selector layer 13 may be turned on at a voltage level that is equal to or higher than the threshold voltage and turned off at a voltage level that is lower than the threshold voltage.

The first selector layer 13 may include an Ovonic Threshold Switching (OTS) material such as diodes and chalcogenide-based materials; a Mixed Ionic Electronic Conducting (MIEC) material such as metal-containing chalcogenide-based materials; a Metal Insulator Transition (MIT) material such as NbO₂, VO₂, or the like; or a tunneling dielectric material with a relatively wide band gap such as SiO₂, Al₂O₃, or the like.

Also, the first selector layer 13 may include a dielectric material containing a dopant implanted through an ion implantation process. Herein, the dielectric material may include a silicon-containing dielectric material such as silicon oxide, silicon nitride, silicon oxynitride, or the like; a dielectric metal oxide; a dielectric metal nitride; or a combination thereof. The dopant may serve to capture conductive carriers moving in the dielectric material or to create trap sites that provide a passage for the captured conductive carriers to move again. To form the trap sites, various elements that create energy potentials capable of accommodating conductive carriers in the dielectric material may be used as the dopant.

For example, when the dielectric material includes a silicon-containing dielectric material, the dopant may include a metal with a valence that is different from the valence of silicon. For example, the dopant may include aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof.

Also, when the dielectric material includes a dielectric metal oxide or a dielectric metal nitride, the dopant may include a metal with a valence different from that of the metal in the metal oxide or metal nitride, or from that of silicon. For example, the first selector layer 13 may include silicon dioxide (SiO₂) that is doped with arsenic (As). When a voltage equal to or higher than the threshold voltage is applied to the first selector layer 13, the conductive carriers may move through the trap sites to realize an on state in which current flows through the first selector layer 13. On the other hand, when the voltage applied to the first selector layer 13 is reduced below the threshold voltage, an off state in which conductive carriers do not move and thus no current flows may be realized.

The first variable resistance layer 15 may be a portion of the first memory cell MC1 that functions to store data. To this end, the first variable resistance layer 15 may have variable resistance characteristics of switching between different resistance states according to the applied voltage. The first variable resistance layer 15 may have a single-layer structure or a multi-layer structure including one or more of various materials used in a Resistive Random Access Memory (RRAM), a Phase-change Random Access Memory (PRAM), a Ferroelectric Random Access Memory (FRAM), a Magnetic Random Access Memory (MRAM), and the like. For example, the materials include metal oxides such as transition metal oxides, perovskite-based materials, and the like; phase-change materials such as chalcogenide-based materials and the like; ferroelectric materials; ferromagnetic materials; and the like. When the first variable resistance layer 15 has a high resistance state, the first memory cell MC1 may store, for example, data ‘0,’ and when the first variable resistance layer 15 has a low resistance state, the first memory cell MC1 may store, for example, data ‘1.’

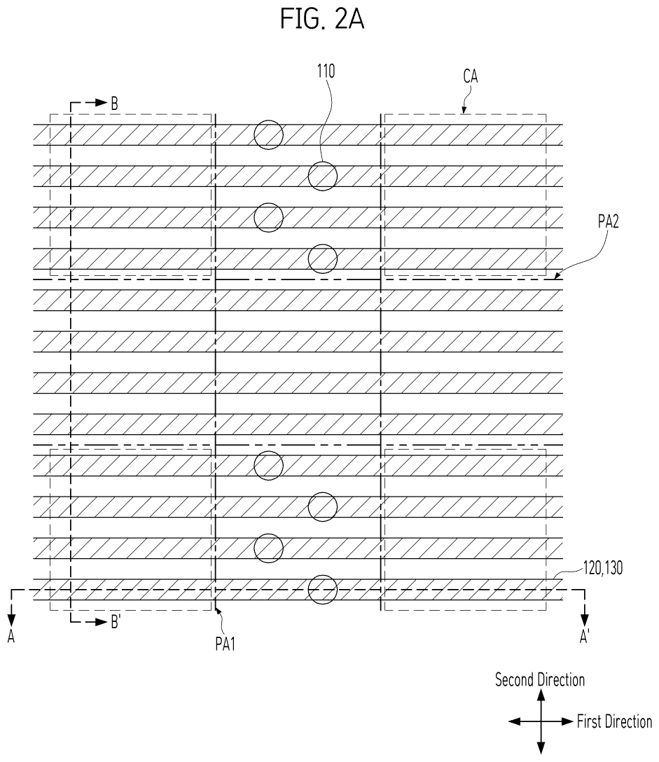

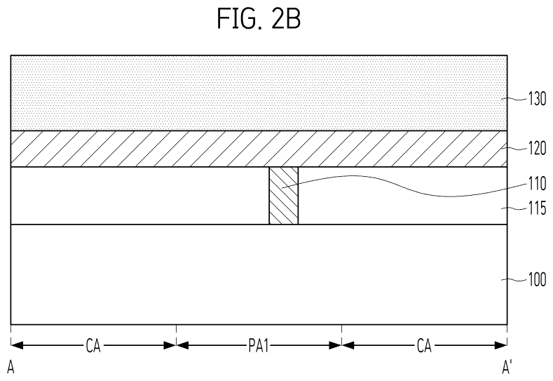

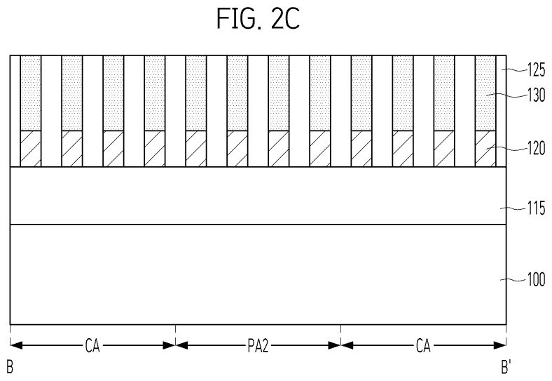

The first memory cells MC1 may have pillar shapes that respectively overlap with the intersection regions between the first lower conductive lines 11 and the first upper conductive lines 17. Although the first memory cell MC1 is illustrated as having a cylindrical shape according to this embodiment of the present disclosure, embodiments are not limited thereto, and the shape of the first memory cell MC1 may be modified in various ways. For example, when the first memory cell MC1 is patterned together with the first lower conductive line 11 and the first upper conductive line 16 as illustrated in the following embodiments illustrated in FIGS. 2A to 8C, the first memory cell MC1 may have a square pillar shape having two sidewalls in the second direction aligned with the first lower conductive line 11 and two sidewalls in the first direction aligned with the first upper conductive line 17. Also, according to this embodiment of the present disclosure, the multiple layers 12 to 16 forming the first memory cell MC1 are illustrated with sidewalls aligned with each other, having been patterned using a single mask, but embodiments are not limited thereto. Also, the multiple layers 12 to 16 may be partially patterned using two or more masks. For example, the first selector layer 13 and the first variable resistance layer 15 may be patterned separately by using different masks, resulting in sidewalls that are not aligned with each other. In this case, the first lower electrode layer 12 may be patterned together with the first selector layer 13, and the first upper electrode layer 16 may be patterned together with the first variable resistance layer 15. Additionally, the first middle electrode layer 14 may be patterned together with either the first selector layer 13 or the first variable resistance layer 15.

Also, the layer structure of the first memory cell MC1 is not limited to the illustrated configuration. The stacking order of the layers may be changed, certain layers may be omitted, or additional layers may be added as needed. For example, one or more of the first lower electrode layer 12, the first middle electrode layer 14, and the first upper electrode layer 16 may be omitted. Also, the positions of the first selector layer 13 and the first variable resistance layer 15 may be reversed. In other words, the first selector layer 13 may be disposed over the first middle electrode layer 14 and the first variable resistance layer 15 may be disposed below the first middle electrode layer 14. Also, one or more additional layers (not shown) may be added to the first memory cell MC1 to enhance either the manufacturing process or the performance characteristics of the first memory cell MC1.

The first lower conductive line 11, the first upper conductive line 17, and the first memory cell MC1 described above may form the first stacked structure ST1. When the second stacked structure ST2 is described later, the description will be made focusing on the difference from the first stacked structure ST1.

The second lower conductive line 21 may be formed over the first upper conductive line 17, with each second lower conductive line 21 designed to overlap with and being in contact with its corresponding first upper conductive line 17. The second lower conductive lines 21 may extend in the second direction, and the second lower conductive lines 21 may be arranged to be spaced apart from each other in the first direction.

The second upper conductive lines 27 may be formed over the second lower conductive lines 21 to be spaced apart from the second lower conductive lines 21 in the vertical direction. The second upper conductive lines 27 may extend in the first direction, and the second upper conductive lines 27 may be arranged to be spaced apart from each other in the second direction. The second upper conductive lines 27 may be formed to respectively overlap with the first lower conductive lines 11 when viewed in a plan view.

The second memory cells MC2 may be disposed between the second lower conductive lines 21 and the second upper conductive lines 27, positioned to overlap with the intersection regions between the second lower conductive lines 21 and the second upper conductive lines 27. The second memory cells MC2 may be formed to overlap with the first memory cells MC1, each second memory cell MC2 overlapping with its corresponding first memory cell MC1 when viewed in a plan view. The second memory cell MC2 may include a second memory unit MU2 where data are actually stored, and a second selector unit SU2 that controls the access to the second memory unit MU2. For example, the second memory cell MC2 may include a stacked structure of a second lower electrode layer 22, a second variable resistance layer 23, a second middle electrode layer 24, a second selector layer 25, and a second upper electrode layer 26.

The second lower conductive line 21, the second upper conductive line 27, and the second memory cell MC2 described above may form the second stacked structure ST2.

In the first stacked structure ST1, the first lower conductive line 11 may function as a word line and the first upper conductive line 17 may function as a bit line. In the second stacked structure ST2, the second lower conductive line 21 may function as a bit line and the second upper conductive line 27 may function as a word line. Since the first upper conductive line 17 and the second lower conductive line 21 contact each other to form a line that is shared by the first stacked structure ST1 and the second stacked structure ST2, they may be called a common bit line.

While the first memory unit MU1 is disposed over the first selector unit SU1 in the first memory cell MC1, the second memory unit MU2 may be disposed below the second selector unit SU2 in the second memory cell MC2. Accordingly, the first memory cell MC1 and the second memory cell MC2 may have a symmetrical layer structure with the first upper conductive line 17 and the second lower conductive line 21, serving as the common bit line, interposed between them. However, embodiments are not limited to this, and the layer structure of the first memory cell MC1 and the second memory cell MC2 may be asymmetrical. For example, the second memory cell MC2 may include the second memory unit MU2 disposed over the second selector unit SU2, similarly to the first memory cell MC1.

Although FIG. 1 illustrates only the cell array area where memory cells are arranged, the semiconductor device in accordance with this embodiment may further include a peripheral circuit area disposed adjacent to the cell array area in the horizontal direction. In this peripheral circuit area, contact plugs coupled to a driving circuit formed in the substrate 10 may be arranged. The memory cells in the cell array area may be relatively far from or relatively close to a peripheral circuit. The memory cells with a relatively short distance from the peripheral circuit will be referred to as near memory cells, and the memory cells with a relatively long distance from the peripheral circuit will be referred to as far memory cells.

To ensure the normal operation of the near memory cells and the far memory cells, it may be necessary to supply a relatively high voltage or current to the conductive lines in the cell array area. However, in this case, excessive current, also known as overshooting current or spike current, may flow to the near memory cells, causing an operation failure of the near memory cells. Described hereinafter are a semiconductor device capable of ensuring the normal operation of both the near memory cells and the far memory cells while preventing an operation failure of the near memory cells, as well as a method for fabricating the semiconductor device.

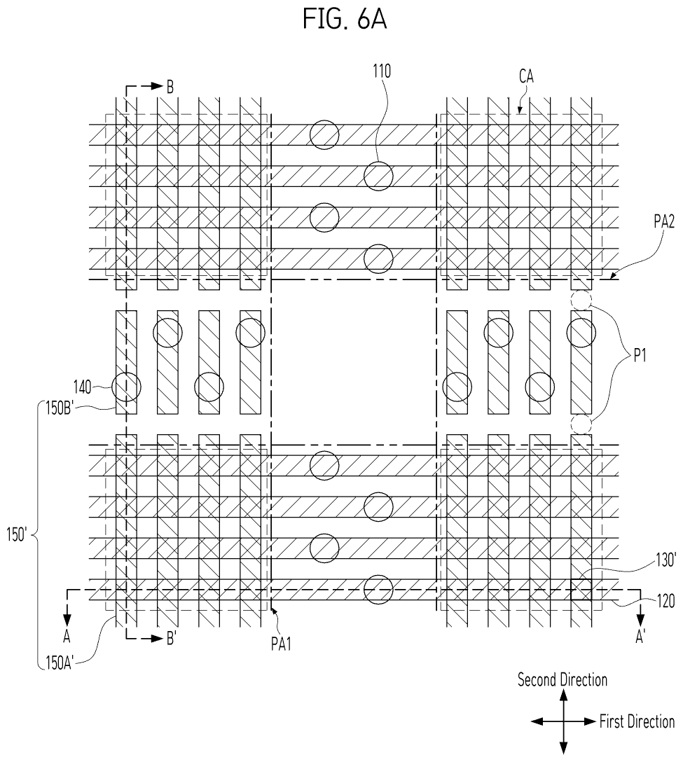

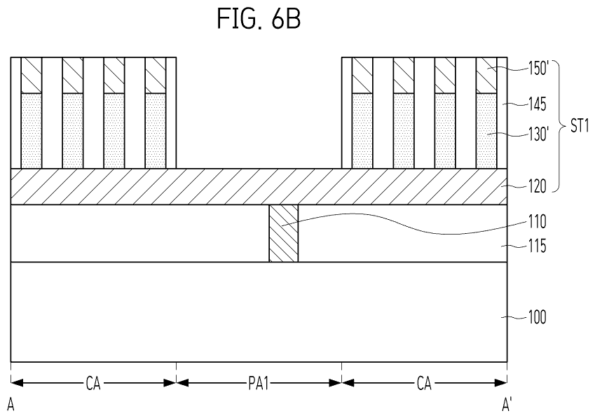

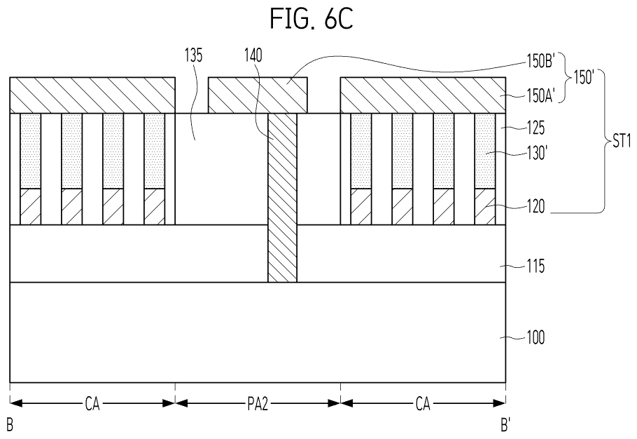

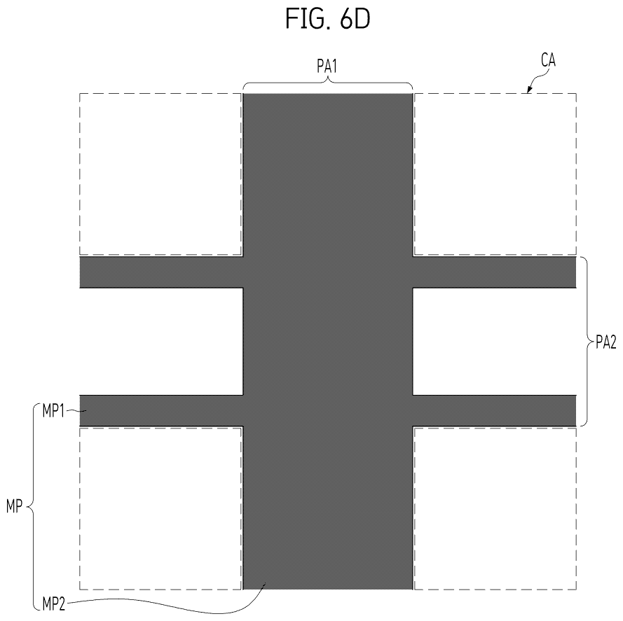

FIGS. 2A to 8C illustrate a semiconductor device and a method for fabricating the same in accordance with another embodiment of the present disclosure. FIGS. 2A, 3A, 4A, 5A, 6A, 7A, and 8A are plan views; FIGS. 2B, 3B, 4B, 5B, 6B, 7B, and 8B are cross-sectional views taken along line A-A′ shown in FIGS. 2A, 3A, 4A, 5A, 6A, 7A, and 8A, respectively; and FIGS. 2C, 3C, 4C, 5C, 6C, and 7C, and FIG. 8C are cross-sectional views taken along line B-B′ shown in FIGS. 2A, 3A, 4A, 5A, 6A, 7A, and 8A, respectively. FIG. 6D is a plan view illustrating a mask pattern used to perform the processes shown in FIGS. 6A to 6C. A detailed description of the parts that are substantially the same as those in the above-described embodiment of the present disclosure will be omitted.

First, the method for fabricating the semiconductor device will be described.

Referring to FIGS. 2A to 2C, a substrate 100 may be provided. The substrate 100 may include a semiconductor material such as silicon. A driving circuit for driving a plurality of memory cells may be formed in the substrate 100. The substrate 100 may include a cell area CA and peripheral circuit areas PA1 and PA2. The cell area CA may be an area where a plurality of memory cells are arranged, and the peripheral circuit areas PA1 and PA2 may be areas where contact plugs coupled to the driving circuit in the substrate 100 are arranged.

According to this embodiment of the present disclosure, four cell areas CA may be arranged to be spaced apart from each other in a 2*2 form in the first direction and the second direction from the perspective of a plan view. The peripheral circuit areas PA1 and PA2 are disposed between the cell areas CA, and the peripheral circuit areas PA1 and PA2 may have a cross shape or a grid shape from the perspective of the plan view. However, embodiments are not limited to this, and the number and arrangement of the cell areas CA and the peripheral circuit areas PA1 and PA2 may be modified in various ways.

For the sake of convenience in description, the peripheral circuit area disposed between the cell areas CA in the first direction is referred to as a first peripheral circuit area PA1, and the peripheral circuit area disposed between the cell areas CA in the second direction is referred to as a second peripheral circuit area PA2. In a diagonal direction crossing the first and second directions, an area where the first peripheral circuit area PA1 and the second peripheral circuit area PA2 overlap with each other may be disposed between the four cell areas CA.

Subsequently, a first lower contact plug 110 and a first inter-layer dielectric layer 115 may be formed over the substrate 100. The first inter-layer dielectric layer 115 may cover the substrate 100 and include one of various dielectric materials including silicon oxide, silicon nitride, silicon oxynitride, and combinations thereof. The first lower contact plug 110 may have a pillar shape penetrating the first inter-layer dielectric layer 115 and may include one or more of various conductive materials. For example, the first lower contact plug 110 may include a metal, such as platinum (Pt), tungsten (W), aluminum (Al), copper (Cu), tantalum (Ta), or the like; a metal nitride, such as titanium nitride (TIN), tantalum nitride (TaN), or the like; or a combination thereof. The first lower contact plug 110 may be interposed between a first lower conductive line 120, which will be described later, and the substrate 100 to electrically connect the first lower conductive line 120 to a portion of the substrate 100, such as a driving circuit.

A plurality of first lower contact plugs 110 may be disposed in the first peripheral circuit area PA1 and arranged in the second direction to respectively overlap with a plurality of first lower conductive lines 120. According to this embodiment of the present disclosure, in order to secure the space between the first lower contact plugs 110, the first lower contact plugs 110 may be arranged in a zigzag formation in the second direction. However, embodiments are not limited to this, and the arrangement of the first lower contact plugs 110 may be modified in various ways. As will be described later, the first lower conductive lines 120 formed in the second peripheral circuit area PA2 may be removed, and the first lower contact plugs 110 may not be disposed in the overlapping area of the first peripheral circuit area PA1 and the second peripheral circuit area PA2. The first lower contact plugs 110 may be formed by depositing a dielectric material layer for forming the first inter-layer dielectric layer 115 over the substrate 100, selectively etching the dielectric material layer to form contact holes that expose portions of the substrate 100, and then filling the contact holes with a conductive material.

Subsequently, a stacked structure 120 and 130 of the first lower conductive line 120 and an initial first memory cell 130 may be formed over the first contact plug 110 and the first inter-layer dielectric layer 115. The stacked structure 120 and 130 may have a line shape extending in the first direction. A plurality of stacked structures 120 and 130 may be arranged to be spaced apart from each other in the second direction. The stacked structures 120 and 130 may be formed with substantially the same line width and spacing in the second direction. This is to facilitate a patterning process for forming the stacked structures 120 and 130.

Accordingly, some of the stacked structures 120 and 130 may extend to intersect with the cell areas CA arranged in the first direction and the first peripheral circuit area PA1 disposed between the cell areas CA, and some of the stacked structures 120 and 130 may extend to intersect with the second peripheral circuit area PA2. The stacked structures 120 and 130 crossing the cell areas CA arranged in the first direction and the first peripheral circuit area PA1 disposed between the cell areas CA may overlap with and contact the first lower contact plugs 110 disposed below the stacked structures 120 and 130. The first lower conductive line 120 and the initial first memory cell 130 may be formed by depositing a conductive material layer for forming the first lower conductive line 120 over the first contact plug 110 and the first inter-layer dielectric layer 115, depositing one or more material layers for forming the initial first memory cell 130, and etching both the conductive material layer and the material layers using a mask pattern of a line shape extending in the first direction.

Subsequently, a second inter-layer dielectric layer 125 may be formed to fill the empty space between the stacked structures 120 and 130 after performing the etching using the mask pattern. The second inter-layer dielectric layer 125 may be formed by depositing a dielectric material until the stacked structures 120 and 130 are covered, and then performing a planarization process, such as Chemical Mechanical Polishing (CMP), on the deposited dielectric material until a top surface of the initial first memory cell 130 is exposed.

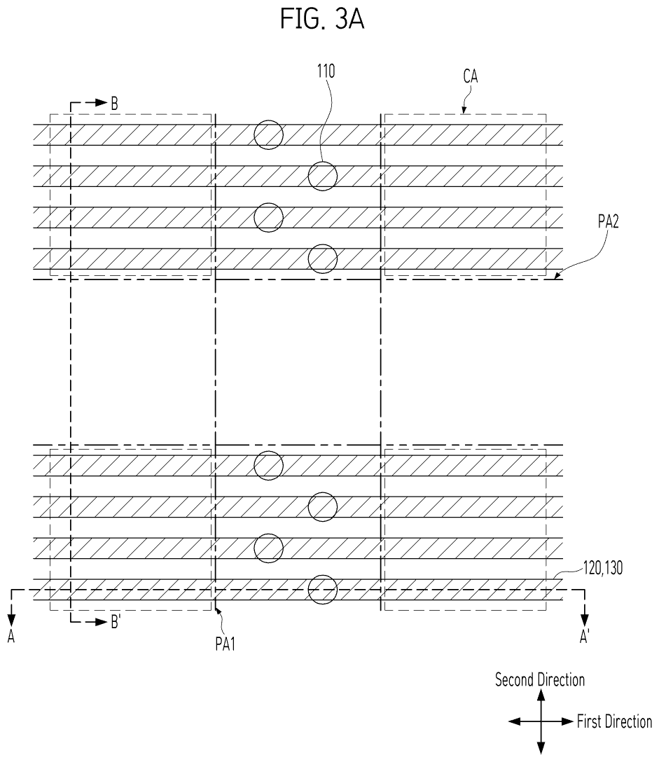

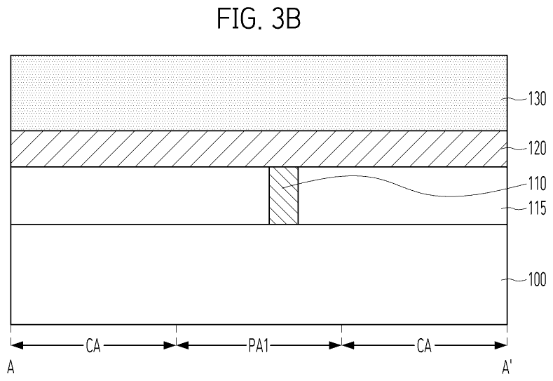

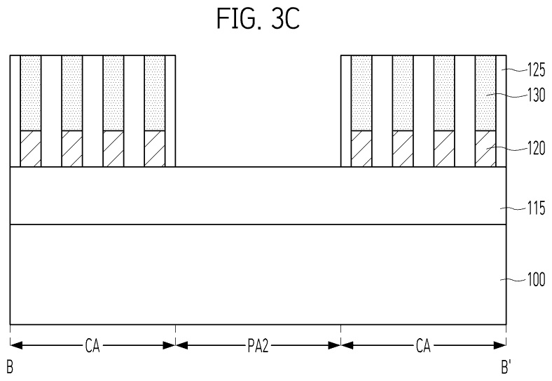

Referring to FIGS. 3A to 3C, the stacked structures 120 and 130 and the second inter-layer dielectric layer 125 in the second peripheral circuit area PA2 may be removed. To be specific, a mask pattern (not shown) that exposes the second peripheral circuit area PA2 is formed over the resultant structure of FIGS. 2A to 2C. Then, using the mask pattern as an etch barrier, the stacked structure 120 and 130 and the second inter-layer dielectric layer 125 in the second peripheral circuit area PA2 may be etched and removed. Although the plurality of stacked structures 120 and 130 are formed in the entire area over the substrate 100 to facilitate the patterning process described above with reference to FIGS. 2A to 2C, it is necessary to remove the stacked structures 120 and 130 in the second peripheral circuit area PA2.

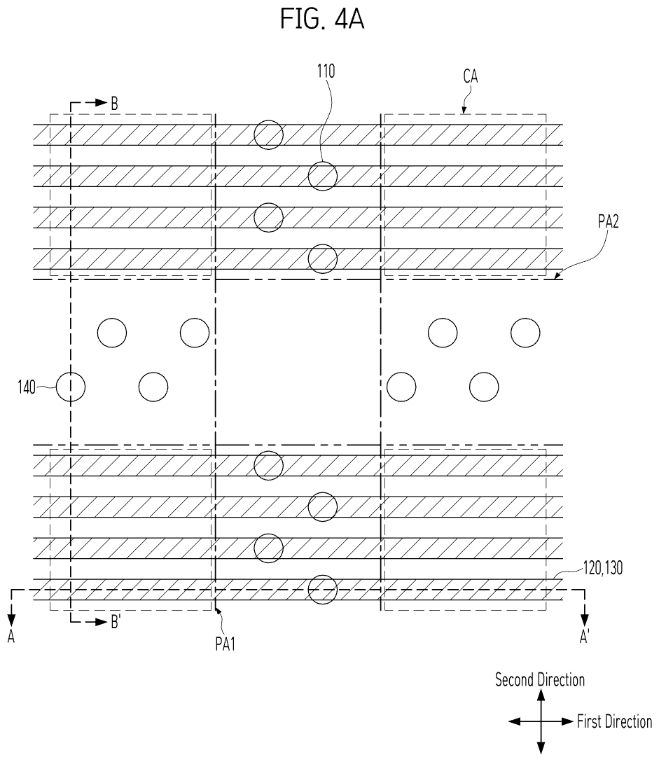

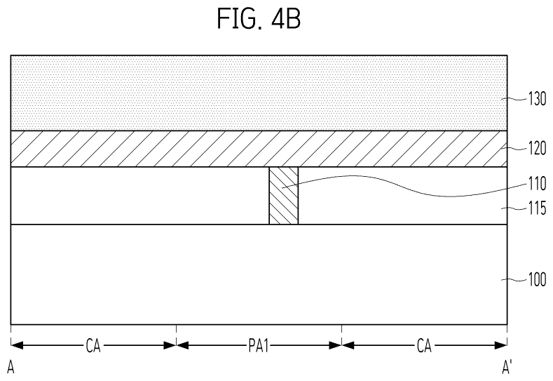

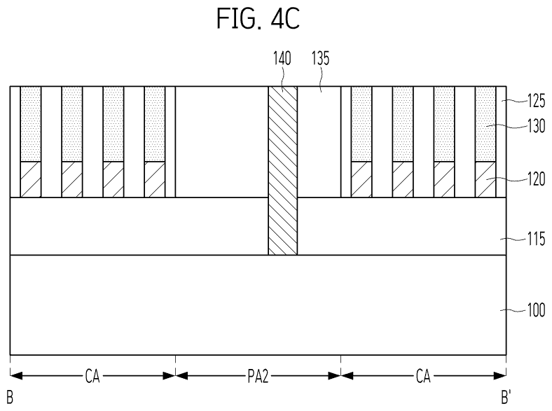

Referring to FIGS. 4A to 4C, a third inter-layer dielectric layer 135 may be formed to fill the empty space generated from the removal process of FIGS. 3A to 3C, that is, to fill the empty space in the second peripheral circuit area PA2. The third inter-layer dielectric layer 135 may be formed by depositing a dielectric material to sufficiently cover the resultant structure of FIGS. 3A to 3C and then performing a planarization process on the deposited dielectric material until the top surface of the initial first memory cell 130 is exposed.

Subsequently, a first upper contact plug 140 of a pillar shape penetrating both the third inter-layer dielectric layer 135 and the first inter-layer dielectric layer 115 may be formed in the second peripheral circuit area PA2. The first upper contact plug 140 may be interposed between a first upper conductive line, which will be described later, and the substrate 100, to electrically connect the first upper conductive line to a portion of the substrate 100, such as a driving circuit. A plurality of first upper contact plugs 140 may be disposed in the second peripheral circuit area PA2 and arranged in the first direction to respectively overlap with the first upper conductive lines. According to this embodiment of the present disclosure, in order to secure the space between the first upper contact plugs 140, the first upper contact plugs 140 may be arranged in a zigzag formation in the first direction. However, embodiments are not limited to this, and the arrangement of the first upper contact plugs 140 may be modified in various ways.

As will be described later, since the first upper conductive lines disposed in the first peripheral circuit area PA1 are removed, the first upper contact plugs 140 may not be disposed in the overlapping area between the first peripheral circuit area PA1 and the second peripheral circuit area PA2. The first upper contact plugs 140 may be formed by selectively etching both the third inter-layer dielectric layer 135 and the first inter-layer dielectric layer 115 to form contact holes that expose portions of the substrate 100, and then filling the contact holes with a conductive material.

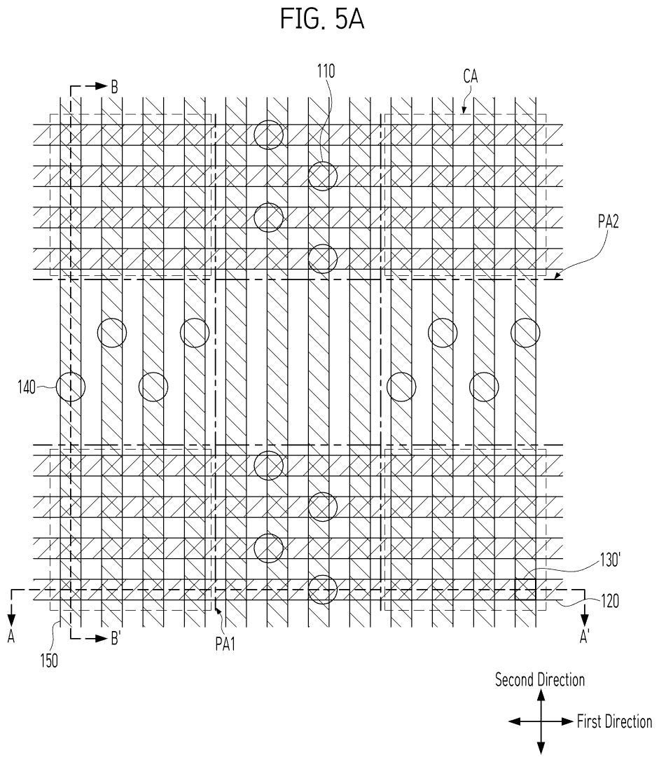

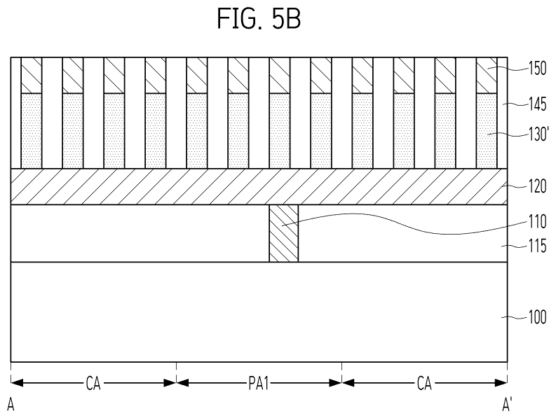

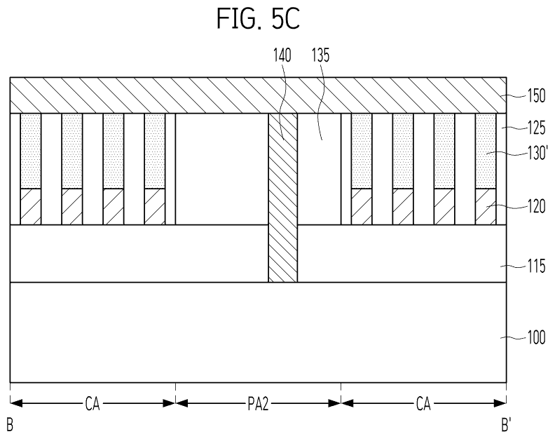

Referring to FIGS. 5A to 5C, first memory cells 130′ may be formed by forming first upper conductive lines 150 over the initial first memory cells 130, the second and third inter-layer dielectric layers 125 and 135, and the first upper contact plugs 140, and then etching the initial first memory cells 130 that are exposed by the first upper conductive lines 150. The first upper conductive lines 150 may have a line shape extending in the second direction and may be arranged to be spaced apart from each other in the first direction. The first upper conductive lines 150 may be formed with substantially the same line width and spacing in the first direction. This is to facilitate a patterning process for forming the first upper conductive lines 150.

Accordingly, some of the first upper conductive lines 150 may extend to cross the cell areas CA that are arranged in the second direction and the second peripheral circuit area PA2 between the cell areas CA, and some of the first upper conductive lines 150 may extend to cross the first peripheral circuit area PA1. The first upper conductive lines 150 crossing the cell areas CA that are arranged in the second direction and the second peripheral circuit area PA2 between the cell areas CA may respectively overlap with and contact the first upper contact plugs 140 that are disposed below the first upper conductive lines 150. The first upper conductive lines 150 may be formed by depositing a conductive material layer for forming the first upper conductive lines 150 over the resultant structure of FIGS. 4A to 4C and etching the conductive material layer using a mask pattern of a line shape extending in the second direction.

The memory cells 130′ may have pillar shapes and be disposed in the intersection regions between the first lower conductive lines 120 and the first upper conductive lines 150. Each of the memory cells 130′ may have two sidewalls aligned with a corresponding first upper conductive line 150 in the first direction and two sidewalls aligned with a corresponding lower conductive line 120 in the second direction. As a result of this process, the first upper conductive lines 150 and the first lower conductive lines 120 intersect with each other in the cell areas CA and in portions of the first peripheral circuit area PA1 that are disposed between the cell areas CA arranged in the first direction. The memory cells 130′ may be arranged in the cell areas CA and in the portions of the first peripheral circuit area PA1 disposed between the cell areas CA arranged in the first direction.

Subsequently, a fourth inter-layer dielectric layer 145 may be formed between the memory cells 130′ and between the first upper conductive lines 150. The fourth inter-layer dielectric layer 145 may be formed by depositing a dielectric material to cover the first upper conductive line 150 and then performing a planarization process on the deposited dielectric material until a top surface of the first upper conductive line 150 is exposed.

Referring to FIGS. 6A to 6C, the first upper conductive lines 150 and the memory cells 130′ disposed in the first peripheral circuit area PA1 may be removed. In the process of FIGS. 5A to 5C, the first upper conductive lines 150 may be formed in the entire area over the substrate 100 to facilitate the patterning process. Therefore, it is necessary to remove the first upper conductive lines 150 and the memory cells 130′ disposed in the first peripheral circuit area PA1.

In the process of removing the first upper conductive lines 150 and the memory cells 130′ disposed in the first peripheral circuit area PA1, portions of the first upper conductive line 150 crossing the second peripheral circuit area PA2 that are adjacent to the cell areas CA in the second direction, specifically first portions P1, may be etched and removed together. Accordingly, in the second direction, the first upper conductive line 150 may be divided into a first segment 150A′ crossing the cell area CA, and a second segment 150B′ crossing the second peripheral circuit area PA2. The first and second segments 150A′ and 150B′ may be spaced apart from each other by the first portion P1. The first upper conductive line divided into the first and second segments 150A′ and 150B′ will be, hereinafter, referred to as a first upper conductive pattern 150′. The first portion P1 of the first upper conductive line 150 that is removed in this process, that is, the area between the first segment 150A′ and the second segment 150B′, may be disposed between the first upper contact plug 140 and the cell area CA from the perspective of a plan view. Accordingly, the second segment 150B′ may overlap with and contact the first upper contact plug 140. This process may include forming a mask pattern over the resultant structure of FIGS. 5A to 5C, and then etching and removing the first upper conductive lines 150, the memory cells 130′, and the fourth inter-layer dielectric layer 145 using the mask pattern as an etch barrier. The mask pattern may expose portions of the second peripheral circuit area PA2 that are adjacent to the cell areas CA in the second direction, correspond to the first portions P1, and extend in the first direction, as well as exposing the first peripheral circuit area PA1. This mask pattern is exemplarily illustrated in FIG. 6D.

Referring to FIG. 6D, the mask pattern may have a shape that exposes a shaded portion and covers the other portions. The shaded portion may include first line portions MP1 and a second line portion MP2. The second line portion MP2 extends in the second direction while overlapping with the first peripheral circuit area PA1. Each of the first line portions MP1 extends in the first direction from the second line portion MP2 and overlaps with a portion of the second peripheral circuit area PA2 that is adjacent to the cell area CA in the second direction and extends in the first direction to overlap with the first portions P1 arranged in the first direction.

As a result, the first stacked structure ST1 including the first lower conductive line 120, the first upper conductive pattern 150′, and the first memory cell 130′ may be formed. Herein, even though the first upper conductive pattern 150′ is divided into a plurality of segments, such as 150A′ and 150B′, in the second direction, voltage or current may be smoothly supplied to the first memory cell 130′ through the first upper conductive pattern 150′ because the segments 150A′ and 150B′ of the first upper conductive pattern 150′ are coupled to each other through a second lower conductive line, which will be described later.

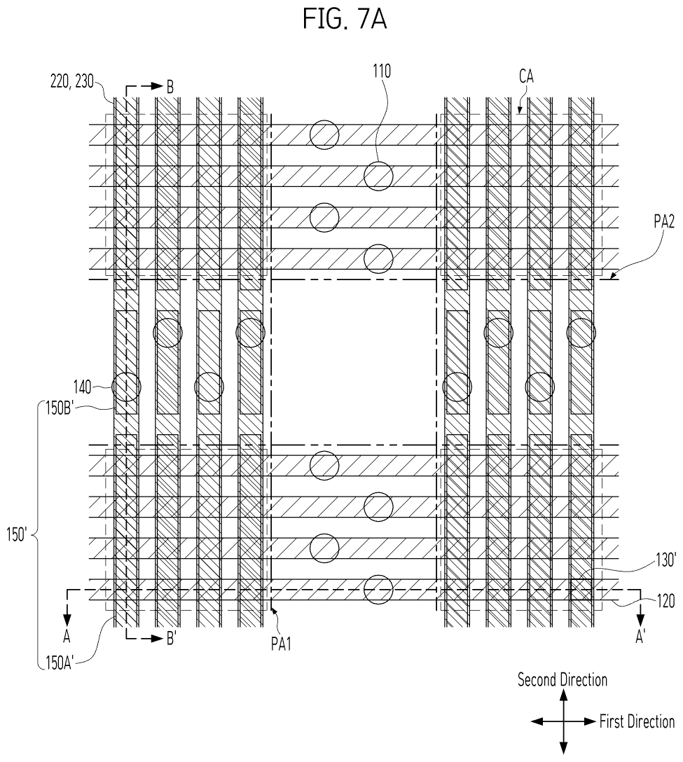

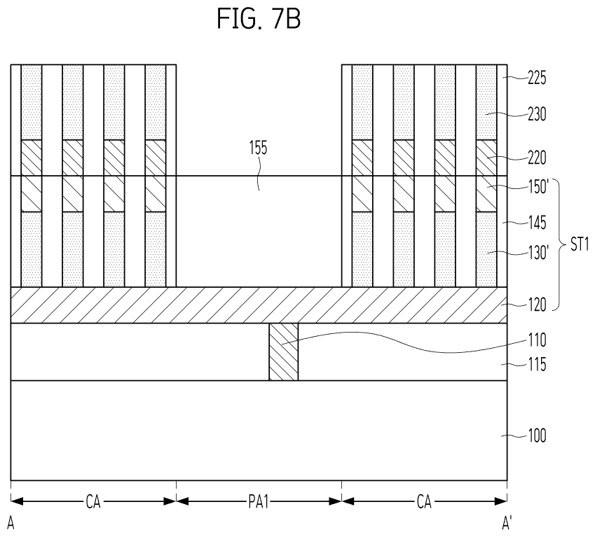

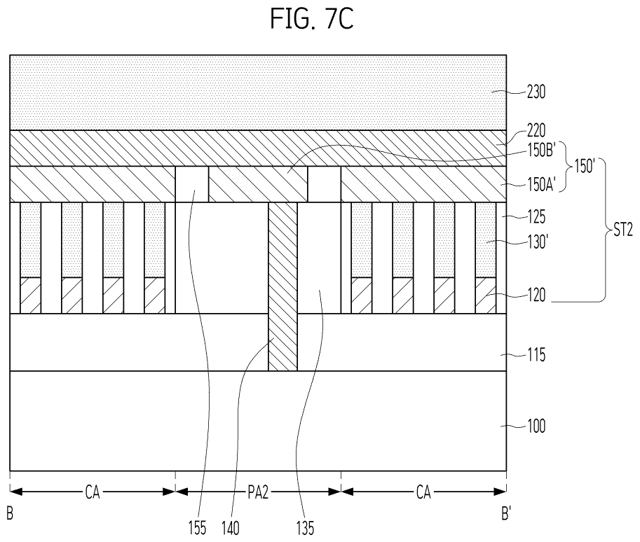

Referring to FIGS. 7A to 7C, a fifth inter-layer dielectric layer 155 may be formed to fill the empty space generated from the removal process of FIGS. 6A to 6C, that is, to fill the empty space in the first peripheral circuit area PA1 and the empty space between the first segment 150A′ and the second segment 150B′ of the first upper conductive pattern 150′ in the second peripheral circuit area PA2. The fifth inter-layer dielectric layer 155 may be formed by depositing a dielectric material to sufficiently cover the resulting structure of FIGS. 6A to 6C and then performing a planarization process on the deposited dielectric material until a top surface of the first upper conductive pattern 150′ is exposed.

Subsequently, a stacked structure 220 and 230 of a second lower conductive line 220 and an initial second memory cell 230 may be formed over the first upper conductive pattern 150′, the fourth inter-layer dielectric layer 145, and the fifth inter-layer dielectric layer 155. The stacked structures 220 and 230 may have a line shape extending in the second direction and may be arranged to be spaced apart from each other in the first direction. The stacked structures 220 and 230 may respectively overlap with the above-described first upper conductive lines 150, and each may contact the first upper conductive pattern 150′. Accordingly, the first and second segments 150A′ and 150B′ of the first upper conductive pattern 150′ may be electrically connected to each other through the second lower conductive line 220. The second lower conductive line 220 may directly contact the top surface of the first upper conductive pattern 150′ and a top surface of the fifth inter-layer dielectric layer 155, which fills the empty space between the first segment 150A′ and the second segment 150B′.

No stacked structures 220 and 230 may exist in the first peripheral circuit area PA1. This is because the stacked structures 220 and 230 and a sixth inter-layer dielectric layer 225 filling the empty space between the stacked structures 220 and 230 are formed in the entire area over the substrate 100 and then stacked structures 220 and 230 and a portion of the sixth inter-layer dielectric layer 225 in the first peripheral circuit area PA1 are etched and removed, which is similar to the process of FIGS. 2A to 3C described above.

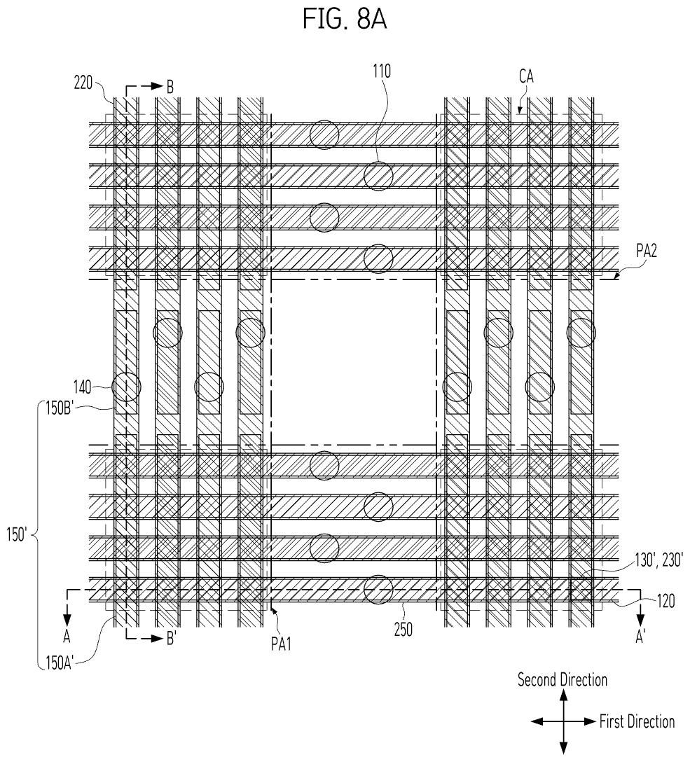

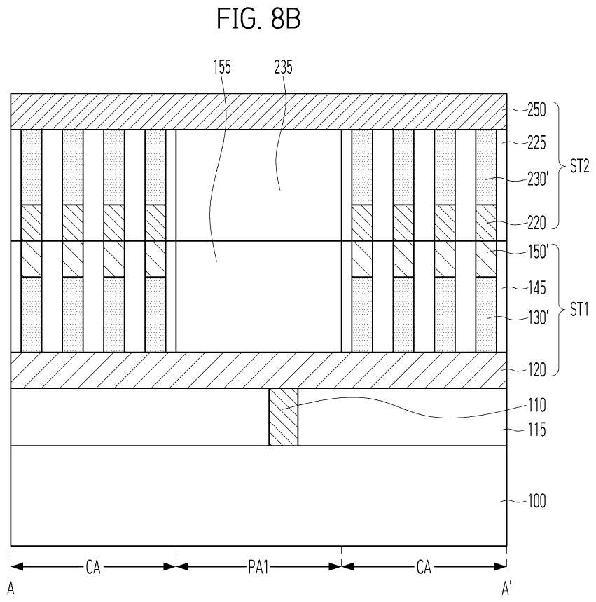

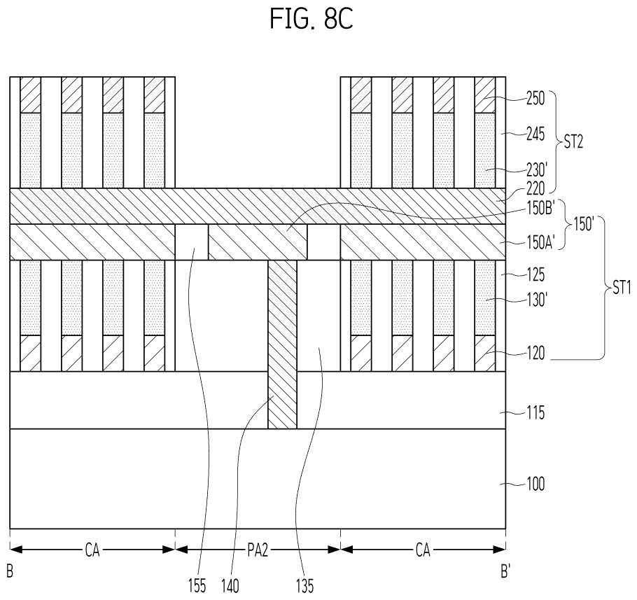

Referring to FIGS. 8A to 8C, a seventh inter-layer dielectric layer 235 may be formed to fill the empty space generated from the removal process of FIGS. 7A to 7C, that is, to fill the empty space in the first peripheral circuit area PA1.

Subsequently, a second memory cell 230′ may be formed by forming a second upper conductive line 250 over the initial second memory cell 230, the sixth inter-layer dielectric layer 225, and the seventh inter-layer dielectric layer 235, and then etching the initial second memory cell 230 that is exposed by the second upper conductive line 250. The second upper conductive line 250 may have a line shape extending in the first direction. A plurality of second upper conductive lines 250 may be arranged to be spaced apart from each other in the second direction. The second upper conductive lines 250 may respectively overlap with the above-described first lower conductive lines 120. The second memory cells 230′ may respectively overlap with the above-described first memory cells 130′. The second memory cell 230′ may have two sidewalls aligned with the second lower conductive line 220 in the first direction and two sidewalls aligned with the second upper conductive line 250 in the second direction. The second upper conductive line 250 and the second memory cell 230′ may not exist in the second peripheral circuit area PA2. This is because the second upper conductive line 250, the second memory cell 230′, and an eighth inter-layer dielectric layer 245 are formed in the entire area over the substrate 100, and then second upper conductive lines 250, second memory cells 230′, and a portion of the eighth inter-layer dielectric layer 245 disposed in the second peripheral circuit area PA2 are removed, which is similar to the process described above with reference to FIGS. 5A to 6C. Although not illustrated, the empty space in the second peripheral circuit area PA2 formed as a result of this removal process may be filled with another inter-layer dielectric layer.

As a result, the second stacked structure ST2 including the second lower conductive line 220, the second upper conductive line 250, and the second memory cell 230′ may be formed. Although not illustrated, a contact plug may be further formed between the second upper conductive line 250 and the substrate 100 to couple the second upper conductive line 250 to the substrate 100.

Through the method for fabricating the semiconductor device described above, the semiconductor device having a cross-point structure and including the first stacked structure ST1 and the second stacked structure ST2 sequentially stacked over the substrate 100 may be formed.

Referring back to FIGS. 8A to 8C, the semiconductor device in accordance with this embodiment of the present disclosure may include the substrate 100 that includes the cell area CA, the first peripheral circuit area PA1 disposed adjacent to the cell area CA in the first direction, and the second peripheral circuit area PA2 disposed adjacent to the cell area CA in the second direction; the first lower conductive lines 120 disposed over the substrate 100 and extending in the first direction to cross the cell area CA and the first peripheral circuit area PA1; the first upper conductive patterns 150′ disposed over the first lower conductive lines 120, extending in the second direction to cross the cell area CA and the second peripheral circuit area PA2, and having a partially cut shape; the first memory cells 130′ disposed between the first lower conductive lines 120 and the first upper conductive patterns 150′ to respectively overlap with the intersection regions between the first lower conductive lines 120 and the first upper conductive patterns 150′; the second lower conductive lines 220 disposed over the first upper conductive patterns 150′ and extending in the second direction while respectively overlapping with and contacting the first upper conductive patterns 150′; the second upper conductive lines 250 disposed over the second lower conductive lines 220 and extending in the first direction to cross the cell area CA and the first peripheral circuit area PA1; and the second memory cells 230′ disposed between the second lower conductive lines 220 and the second upper conductive lines 250 to respectively overlap with the intersection regions between the second lower conductive lines 220 and the second upper conductive lines 250.

As described above, each of the first upper conductive patterns 150′ may include the first segment 150A′ crossing the cell area CA, and a second segment 150B′ disposed in the second peripheral circuit area PA2 to be separated from the first segment 150A′. The first upper conductive patterns 150′ may respectively overlap with and contact the second lower conductive lines 220. Accordingly, even though the first segment 150A′ and the second segment 150B′ are separated from each other, it is possible to electrically connect the first segment 150A′ and the second segment 150B′ to each other through the second lower conductive line 220.

Detailed description on the constituent elements of the semiconductor device in accordance with this embodiment of the present disclosure may be omitted herein since they are already described earlier in the description on the method for fabricating the semiconductor device.

The semiconductor device and the method for fabricating the semiconductor device described above may have the following advantages.

According to this embodiment of the present disclosure, voltage or current may be supplied to the memory cells 130′ and 230′ in the cell area CA through the first upper contact plug 140 disposed in the second peripheral circuit area PA2 and through a common line that is formed by the first upper conductive pattern 150′ and the second lower conductive line 220. Herein, the voltage or current may be supplied only through the second lower conductive line 220 in the portion P1 where the first upper conductive pattern 150′ is cut. In other words, the resistance of the common line may significantly increase just before the voltage or current is supplied to the cell area CA in the second direction. This increase in resistance can prevent and/or reduce the phenomenon of excessive current flowing through a near memory cell, particularly those close to the second peripheral circuit area PA2 among the memory cells 130′ and 230′.

Also, except for the portion P1 where the first upper conductive pattern 150′ is cut, since the memory cells 130′ and 230′ are driven through the common line formed by the first upper conductive pattern 150′ and the second lower conductive line 220, the resistance of the common line may be relatively low, making it easy to drive the memory cells 130′ and 230′.

Furthermore, the process of forming the first upper conductive pattern 150′ with the cut shape may be performed not by using an additional mask and etching process, but by modifying the shape of the mask during the process of removing the first upper conductive line 150 in the first peripheral circuit area PA1. Therefore, this approach has an advantage of not increasing process complexity or difficulty.

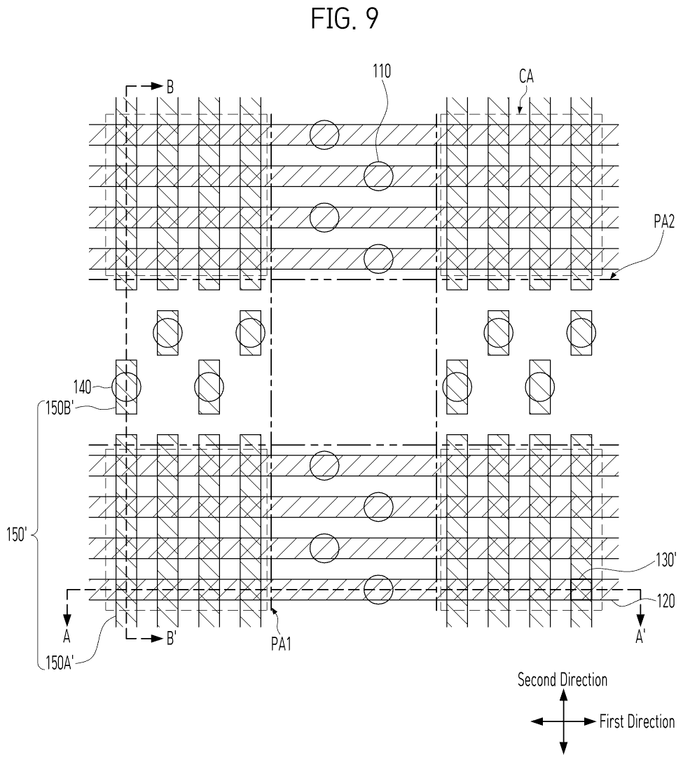

FIG. 9 is a plan view illustrating a semiconductor device in accordance with another embodiment of the present disclosure. FIG. 9 may correspond to the process shown in the FIG. 6A. Hereinafter, the description will focus on the difference from what is illustrated in FIG. 6A.

Referring to FIG. 9, when the first upper conductive line 150 and the memory cell 130′ in the first peripheral circuit area PA1 are removed, a portion of the first upper conductive line 150 adjacent to the cell area CA in the second direction may be etched and removed together. Accordingly, in the second direction, the first upper conductive line 150 may be divided into a first segment 150A′ crossing the cell area CA, and a second segment 150B′ crossing the second peripheral circuit area PA2. These segments 150A′ and 150B′ may be spaced apart from each other.

Compared to FIG. 6A, the size of the second segment 150B′ may be reduced in FIG. 9. In FIG. 6A, first ends, e.g., upper ends, of the second segments 150B′ arranged in the first direction may be aligned with each other, and second ends, e.g., lower ends, of the second segments 150B′ may be aligned with each other, with respect to the orientation of FIG. 6A. Meanwhile, in FIG. 9, first ends of the second segments 150B′ may not be aligned with each other, and second ends of the second segments 150B′ may not be aligned with each other. For example, the first ends of the second segments 150B′ may be arranged in a zigzag formation, and the second ends of the second segments 150B′ may also be arranged in a zigzag formation.

In the case of this embodiment of the present disclosure, since the length of the second segment 150B′ is decreased, the resistance of the common line formed by the first upper conductive line 150 and the second lower conductive line overlapping with the first upper conductive line 150 may be further increased. Accordingly, the phenomenon of excessive current flowing through the near memory cell may be further prevented and/or reduced.

According to the embodiments of the present disclosure, the semiconductor device and the method for fabricating the semiconductor device may be able to prevent defects in the near memory cells and ensure the normal operation of all memory cells.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a substrate including a cell area, a first peripheral circuit area disposed adjacent to the cell area in a first direction, and a second peripheral circuit area disposed adjacent to the cell area in a second direction intersecting with the first direction, the first and second directions being parallel to a top surface of the substrate;
a plurality of first lower conductive lines disposed over the substrate, extending in the first direction, and crossing both the cell area and the first peripheral circuit area;
a plurality of first upper conductive patterns disposed over the first lower conductive lines, extending in the second direction, and crossing both the cell area and the second peripheral circuit area, each of the first upper conductive patterns including a first segment disposed in the cell area and a second segment disposed in the second peripheral circuit area, the second segment being separated from the first segment;
a plurality of first memory cells disposed in intersection regions between the first lower conductive lines and the first segments of the first upper conductive patterns;
a plurality of second lower conductive lines extending in the second direction and disposed over the first upper conductive patterns, each of the second lower conductive lines overlapping with and contacting a corresponding one of the first upper conductive patterns;
a plurality of second upper conductive lines disposed over the second lower conductive lines, extending in the first direction, and crossing both the cell area and the first peripheral circuit area; and
a plurality of second memory cells disposed in intersection regions between the second lower conductive lines and the second upper conductive lines.

2. The semiconductor device of claim 1, wherein the first segment and the second segment are electrically connected to each other through a corresponding one of the second lower conductive lines.

3. The semiconductor device of claim 1, further comprising:
first lower contact plugs disposed between the first lower conductive lines and the substrate, each overlapping with a corresponding one of the first lower conductive lines in the first peripheral circuit area.

4. The semiconductor device of claim 1, further comprising:
first upper contact plugs disposed between the first upper conductive patterns and the substrate, each overlapping with a corresponding one of the first upper conductive patterns in the second peripheral circuit area.

5. The semiconductor device of claim 4, wherein an area between the first segment and the second segment is disposed between a corresponding one of the first upper contact plugs and the cell area from a perspective of a plan view.

6. The semiconductor device of claim 1, further comprising:
a dielectric layer buried between the first segment and the second segment,
wherein the second lower conductive lines directly contact a top surface of the dielectric layer.

7. The semiconductor device of claim 1, wherein each of the first memory cells and the second memory cells includes:
a variable resistance layer; and
a selector layer disposed over or below the variable resistance layer and electrically connected to the variable resistance layer.

8. The semiconductor device of claim 1, wherein a first memory cell has four sidewalls aligned with both sidewalls of a corresponding first lower conductive line and both sidewalls of a corresponding first upper conductive pattern, and
a second memory cell has four sidewalls aligned with both sidewalls of a corresponding second lower conductive line and both sidewalls of a corresponding second upper conductive line.

9. A method for fabricating a semiconductor device, the method comprising:
providing a substrate including a cell area, a first peripheral circuit area disposed adjacent to the cell area in a first direction, and a second peripheral circuit area disposed adjacent to the cell area in a second direction intersecting with the first direction, the first and second directions being parallel to a top surface of the substrate;
forming a plurality of first lower conductive lines that are disposed over the substrate, extend in the first direction, and cross both the cell area and the first peripheral circuit area;
forming a plurality of first upper conductive patterns that are disposed over the first lower conductive lines, extend in the second direction, and cross both the cell area and the second peripheral circuit area, each of the first upper conductive patterns including a first segment disposed in the cell area and a second segment disposed in the second peripheral circuit area, the second segment being separated from the first segment;
forming a plurality of first memory cells that are disposed in intersection regions between the first lower conductive lines and the first segments of the first upper conductive patterns;
forming a plurality of second lower conductive lines that extend in the second direction and are disposed over the first upper conductive patterns, each of the second lower conductive lines overlapping with and contacting a corresponding one of the first upper conductive patterns;
forming a plurality of second upper conductive lines that are disposed over the second lower conductive lines, extend in the first direction, and cross both the cell area and the first peripheral circuit area; and
forming a plurality of second memory cells that are disposed in intersection regions between the second lower conductive lines and the second upper conductive lines.

10. The method of claim 9, wherein the forming of the first upper conductive patterns includes:
forming a plurality of first upper conductive lines that extend in the second direction and cross the cell area, the first peripheral circuit area, and the second peripheral circuit area; and
removing first upper conductive lines disposed in the first peripheral circuit area among the first upper conductive lines, and removing a first portion of each of the remaining first upper conductive lines among the first upper conductive lines, the first portion being adjacent to the cell area.

11. The method of claim 10, further comprising:
forming first upper contact plugs that are disposed between the first upper conductive patterns and the substrate, each of the first upper contact plugs overlapping with a corresponding one of the first upper conductive patterns in the second peripheral circuit area,
wherein the first portion is disposed between the first upper contact plug and the cell area from a perspective of a plan view.

12. The method of claim 10, wherein the removing of the first portion includes:
forming a mask pattern that exposes a first line portion overlapping with the first peripheral circuit area and a second line portion overlapping with the first portion, the first line portion extending in the second direction, the second line portion extending in the first direction from the first line portion over a resultant structure where the first upper conductive lines are formed; and
etching the first upper conductive lines using the mask pattern as an etch barrier.

13. The method of claim 9, further comprising:
forming first lower contact plugs that are disposed between the first lower conductive lines and the substrate, each of the first lower contact plugs overlapping with a corresponding one of the first lower conductive lines in the first peripheral circuit area.

14. The method of claim 9, wherein the forming of the first lower conductive lines and the first memory cells includes:
forming a conductive layer for forming the first lower conductive lines and material layers for forming the first memory cells over the substrate;
forming the first lower conductive lines and initial first memory cells aligned with the first lower conductive lines over the first lower conductive lines by selectively etching the conductive layer and the material layers; and
forming the first memory cells by etching the initial first memory cells that are exposed by the first upper conductive patterns.

15. The method of claim 9, wherein the forming of the second lower conductive lines and the second memory cells includes:
forming a conductive layer for forming the second lower conductive lines and material layers for forming the second memory cells over the first upper conductive patterns;
forming the second lower conductive lines and initial second memory cells aligned with the second lower conductive lines over the second lower conductive lines by selectively etching the conductive layer and the material layers; and
forming the second memory cells by etching the initial second memory cells that are exposed by the second upper conductive lines.

16. The method of claim 9, further comprising:
after the forming of the first upper conductive patterns,
forming a dielectric layer that fills space between the first segment and the second segment,
wherein the second lower conductive lines contact a top surface of the dielectric layer.

17. The method of claim 9, wherein each of the first and second memory cells includes:
a variable resistance layer; and
a selector layer disposed above or below the variable resistance layer and electrically connected to the variable resistance layer.
